(19) United States
(12) Patent Application Publication
(10) Pub. No.: US 2006/0289982 A1
(43) Pub. Date: Dec. 28, 2006

(54) Semiconductor device and method for producing same

(75) Inventor: Akinori Miura, Kurokawa-gun (JP)

Correspondence Address: BIRCH STEWART KOLASCH & BIRCH, PO BOX 747, FALLS CHURCH, VA, 22040-0747, US

(73) Assignee: FUJI PHOTO FILM CO., LTD.

(21) Appl. No.: 11/471,577

(22) Filed: Jun. 21, 2006

(30) Foreign Application Priority Data
Jun. 22, 2005 (JP) P2005-182426
Jul. 6, 2005 (JP) P2005-197852
Jan. 11, 2006 (JP) P2006-3928

(51) Int. Cl. H01L 23/48

(52) U.S. Cl. 257/690

(57) ABSTRACT

A semiconductor device is provided and includes: an interlayer insulating layer and a wiring layer provided above a surface of a semiconductor substrate having an element region. At least a portion of the interlayer insulating layer containing impurities in contact with the wiring layer has been removed at the edge portion of the semiconductor substrate.

### FIELD OF THE INVENTION

The present invention relates to a semiconductor device and a method for producing the same and more particularly to a wiring structure for chip edge portion useful for chip size package (CSP) type solid imaging element, etc.

### BACKGROUND OF THE INVENTION

There has been a growing demand for the reduction of the size of solid imaging elements containing CCD (charge coupled device) from the standpoint of necessity for application to cellular phone, digital cameral, etc. As one of solutions to the demand, there has been proposed a CSP type solid imaging element including a micro lens provided on the light-receiving area of semiconductor chip (JP-A-7-202152).

The use of the CSP type solid imaging element makes it possible to reduce the required mounting area. Further, in the CSP type solid imaging element, optical parts such as filter, lens and prism can be bonded to the surface of hermetically sealed portion, making it possible to reduce the mounting size without deteriorating the light collecting power of microlens.

However, the CSP type solid imaging element is disadvantageous in that in order to mount terminals for taking out signals on the solid imaging element, these terminals need to be mounted on and electrically connected to the substrate for the mounting of the solid imaging element by bonding or like method and sealed, requiring many steps and hence much time for mounting.

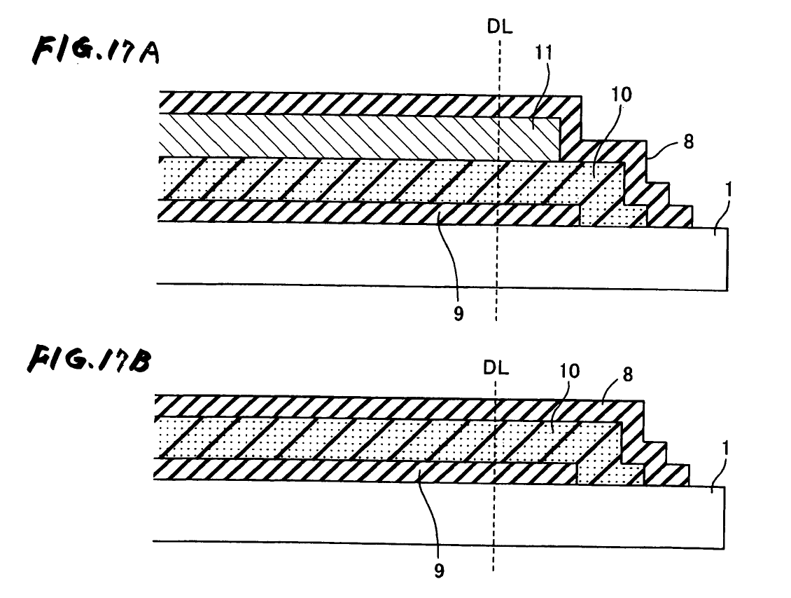

In recent years, there has been proposed a method which includes dicing the semiconductor substrate along the line extending across the wiring region so that terminals can be externally drawn from the side surface of the substrate. An example of this configuration is shown in FIGS. 17A and 17B. As can be seen in these figures, a wiring layer 11 composed of aluminum layer is formed on BPSG layer 10 which is a leveling layer. The wiring layer 11 is covered by a protective layer 8 to form a wiring structure. When the semiconductor substrate is cut at the dicing line DL, BPSG layer 10 is exposed. Since BPSG layer contains impurities such as boron B and phosphorus P and thus can easily take water content therein, it becomes electrically conductive with acid produced by the reaction of these impurities with water content and thus is subject to short-circuiting. Further, when the wiring is made of an oxidizable material such as aluminum, short-circuiting can easily occur.

A color filter is formed on these layers. When the edge portion of the substrate is raised, there arises a problem that unevenness in coating due to difference in level can easily occur.

### SUMMARY OF THE INVENTION

An object of an illustrative, non-limiting embodiment of the invention is to provide a semiconductor device having a high precision and a high reliability which is not subject to short-circuiting or breakage.

Another object of an illustrative, non-limiting embodiment of the invention is to enhance the reliability of a semiconductor device during taking out signals from the side surface thereof in particular.

A semiconductor device according to an aspect of the invention includes an interlayer insulating layer and a wiring layer for taking out signals, which is provided above a surface of a semiconductor substrate having an element region. The interlayer insulating layer containing impurities and coming into contact with the wiring layer is removed at the edge portion of the semiconductor substrate.

In this arrangement, no interlayer insulating layers such as BPSG (boro phospho silicate glass) are exposed at the cross section, causing no wiring short-circuiting due to water content taken from the air even if the semiconductor device comes in contact with the air. Further, the deterioration of wiring can be prevented, making it possible to inhibit the occurrence of defects in bonding.

In the semiconductor device, the interlayer insulating layer containing impurities may be a BPSG layer or PSG layer.

The semiconductor device may include a stopper insulating layer (i.e., an insulating layer acting as a stopper) having etching selectivity with respect to the interlayer insulating layer, which is provided under the interlayer insulating layer.

In this arrangement, a stopper insulating layer is provided to give good insulation properties with the underlying layer. Further, a field oxide layer can be formed without etching, making it possible to enhance reliability.

In the semiconductor device, the stopper insulating layer may contain silicon nitride.

In this arrangement, good insulation properties can be provided. The region which no flat layer is provided is a layered product of silicon nitride and field oxide layer as silicon oxide. Thus, both insulation properties and moistureproofness are good.

In the semiconductor device, the interlayer insulating layer containing impurities can be removed over the entire edge portion of the semiconductor device.

In this arrangement, any difference in level can be eliminated at the edge portion of the semiconductor device, making it possible to prevent the occurrence of unevenness in coating when the filter material is spread during the formation of the color filter.

In the semiconductor device, the wiring layer may be exposed at the edge portion of the semiconductor substrate and may be externally connected through a wiring lead formed on the side surface of the semiconductor substrate.

In this arrangement, the length of the wiring can be reduced efficiently, allowing reduction of wiring resistivity as well as provision of semiconductor device having good properties.

In the semiconductor device, the wiring layer may be a metallic layer.

In the semiconductor device, the metallic layer may contain aluminum or aluminum alloy.

Although aluminum is disadvantageous in that when exposed to the air with impurity ions, it is subject to oxidation and breakage, the reliability of the semiconductor device can be enhanced in this arrangement.

The semiconductor device may be a solid imaging element that constitutes a chip size package.

In this arrangement, the size of the semiconductor device can be further reduced.

According to an aspect of the invention, a method for producing a semiconductor device including an interlayer insulating layer and a wiring layer for taking out signals, which are provided on the surface of a semiconductor substrate having an element region, the method including a step of selectively removing at least a portion of the interlayer insulating containing impurities and coming in contact with the wiring layer at the edge portion of the semiconductor substrate.

In accordance with the production method, a wiring structure having no impurity-containing interlayer insulating layer such as BPSG (boro phospho silicate glass) layer exposed at the cross section of chip can be formed without increasing the number of required steps merely by changing the mask pattern during the patterning of the interlayer insulating layer, allowing wiring without causing short-circuiting in wiring due to water content which could be taken from the air even if the section of chip comes in contact with the air.

The production method may include a step forming a stopper insulating layer before forming the interlayer insulating layer, the stopper insulating layer having a different etching rate from the interlayer insulating layer and acting as a stopper in the selectively removing of the interlayer insulating layer.

In accordance with the production method, the interlayer insulating layer can be safely removed without removing the underlying layer.

In the production method, the stopper insulating layer may be formed in the same step as that of forming an ONO structure gate oxide layer.

In accordance with the production method, the interlayer insulating layer can be safely removed without adding any new step merely by changing the mask pattern during the patterning of gate oxide layer. Further, the provision of a dense silicon nitride layer having a high moistureproofness makes it possible to prevent the occurrence of short-circuiting.

In the production method, the stopper insulating layer may be formed in the same step as that of forming an anti-reflection layer.

In accordance with the production method, the interlayer insulating layer can be safely removed without adding any new step merely by changing the mask pattern during the patterning of anti-reflection layer.

In the production method, the stopper insulating layer may be a layered product of: a silicon nitride layer formed in the same step as that for the ONO structure gate oxide layer; and a silicon nitride layer formed in the same step as that for the anti-reflection layer.

In accordance with the production method, the interlayer insulating layer can be safely removed without adding any new step merely by changing the mask pattern during the patterning of a gate oxide layer and an anti-reflection layer, making it possible to exert a more secure passivation effect.

The production method may include: a step of forming a plurality of solid imaging elements on the surface of the semiconductor substrate; a step of connecting light-transmitting members to the surface of the semiconductor substrate in such an arrangement that the respective light-transmitting members are opposed to the respective light-receiving regions of the solid imaging elements; a step of dicing the semiconductor substrate in such an arrangement that the wiring layer on the semiconductor substrate is partly exposed at the side surface of the semiconductor substrate; a step of forming an external connecting terminal to the side surface of the semiconductor substrate in correspondence to the solid imaging elements; and a step of separating the connected product formed in the connecting step and having an external connecting terminal on the respective solid imaging elements into respective solid imaging elements.

In accordance with the production method, all the elements are positioned on wafer level and then mounted and integrated altogether before being separated into respective solid imaging elements, making it easy to form a solid imaging element having a high reliability. From the standpoint of light receiving efficiency, the light-transmitting member is preferably formed so as to have a clearance opposed to the light receiving region.

In the production method, the step of forming the external connecting terminal includes a step of forming a terminal pattern in contact with a side surface of the wiring layer at the side surface of the semiconductor substrate by using an ink jet method.

In accordance with the production method, a high precision pattern can be formed at a good efficiency, allowing a high reliability electrode drawing.

A semiconductor device according to another aspect of the invention includes an interlayer insulating layer containing impurities and a wiring layer, which are provided on the surface of a semiconductor substrate having an element region. An underlayer having etching selectivity with respect to the interlayer insulating layer is formed under the wiring layer at the edge portion of the semiconductor substrate.

In this arrangement, the interlayer insulating layer containing impurities such as BPSG (boro phospho silicate glass) layer under the wiring layer can be removed from the cross section of the semiconductor (substrate) chip. The wiring layer comes in contact with the underlayer. Thus, the deterioration of wiring can be prevented, making it possible to inhibit the occurrence of bonding defectives. By forming the underlayer in such an arrangement that it is somewhat wider than the wiring layer, the wiring layer can be covered by the passivation layer over the entire edge thereof.

In the semiconductor device, the interlayer insulating layer containing impurities may be a BPSG layer or PSG layer.

In the semiconductor device, a silicon conductive layer may be provided under the interlayer insulating layer at the edge portion of the semiconductor substrate.

In this arrangement, the conductive layer acts as a stopper during the etching of the interlayer insulating layer. Further, due to the electrical conductivity of the conductive layer, the region which acts as a terminal for taking out signals, i.e., contact area can be raised by the amount of the conductive layer. Accordingly, even when the wiring layer has an interlayer insulating layer containing impurities disposed on the side surface thereof and thus undergoes some deterioration due to doping from the interlayer, the presence of the conductive layer under the wiring layer makes it possible to avoid substantial malcontact. As a result of etching of interlayer insulating layer leading to the formation of recessed portions for the formation of wiring layer, a wiring layer can be formed on these recessed portions, making it possible to eliminate difference in level at the edge portion of the substrate and hence prevent the occurrence of unevenness in coating during the spreading of the filter material at the step of forming a color filter.

In the semiconductor device, a silicon conductive layer may be provided under the interlayer insulating layer at the edge portion of the semiconductor substrate.

In this arrangement, the interlayer insulating layer can be formed with a silicon conductive layer as a stopper, making it possible to form a field oxide layer without etching and hence enhance the reliability of the semiconductor device. Further, since the silicon conductive layer such amorphous silicon and polycrystalline silicon is used as a gate electrode or as a charge transferring electrode in a solid imaging element, it can be formed merely by changing somewhat the patterning mask for the layer to be used in the element region in the substrate. Accordingly, a semiconductor device having a high reliability can be obtained without increasing the number of required production steps.

In the semiconductor device, the underlayer may be a non-doped insulating layer.

In this arrangement, the interlayer insulating layer can be removed at the edge portion of the substrate with the non-doped insulating layer as a stopper, making it possible to form a field oxide layer without etching and hence enhance the reliability of the semiconductor device.

In the semiconductor device, the stopper may contain polycrystalline silicon.

In this arrangement, the polycrystalline silicon acts as a good etching stopper with respect to the interlayer insulating layer such as BPSG and PSG, making it possible to enhance the reliability of the semiconductor device. Further, since the polycrystalline silicon comes in contact with the wiring layer to increase the substantial thickness of the wiring layer for taking out signals, the contact area with the wiring lead, too, can be raised, making it possible to form a layer having a high reliability.

In the semiconductor device, the wiring layer may be exposed at the edge portion of the semiconductor substrate and may be externally connected through a wiring lead formed on the side surface of the semiconductor substrate.

In this arrangement, the wiring length can be reduced efficiently, allowing reduction of wiring resistivity as well as provision of semiconductor device having good properties.

The semiconductor device may include a protective layer formed above the wiring layer, and the wiring layer may be surrounded by the underlayer and the protective layer on cross section of the edge portion of the semiconductor substrate.

In this arrangement, the periphery of the wiring layer is surrounded by the protective layer and the underlayer so that it cannot come in contact with the insulating layer containing impurities, giving an extremely high reliability.

In the aforementioned semiconductor device, the wiring layer may be a metallic layer.

In the semiconductor device, the metallic layer may contain aluminum or aluminum alloy.

Although aluminum is disadvantageous in that when exposed to the air with impurity ions, it is subject to oxidation and breakage, the reliability of the semiconductor device can be enhanced in this arrangement.

The semiconductor device may be a solid imaging element that constitutes a chip size package.

In this arrangement, the size of the semiconductor device can be further reduced.

According to another aspect of the invention, a method for producing a semiconductor device including an interlayer insulating layer containing impurities and a wiring layer for taking out signals, which are provided above a surface of a semiconductor substrate having an element region, the method including a step of forming a silicon conductive layer under the interlayer insulating layer, corresponding to a region where the wiring layer for taking out signals is to be formed, a step of selectively removing the interlayer insulating layer with the silicon conductive layer as an etching stopper and a step of forming the wiring layer for taking out signals above the silicon conductive layer, whereby the interlayer insulating layer is selectively removed at the edge portion of the semiconductor substrate in such an arrangement that the distance between the wiring layer and the interlayer insulating layer at the side surface of the semiconductor substrate is greater than the width of the wiring layer.

In accordance with the production method, the interlayer insulating layer is selectively removed with the silicon conductive layer as an etching stopper, making it possible to form a wiring structure the distance of which between the wiring layer and the interlayer insulating layer at the side surface of the semiconductor substrate of the interlayer insulating layer containing impurities such as BPSG (boro phospho silicate glass) layer is sufficiently greater than the width of the wiring layer at the position without increasing the number of required steps merely by changing the mask pattern during the patterning of the interlayer insulating layer. Accordingly, wiring can be made without causing short-circuiting in wiring due to water content which could be taken in thereby from the air even if the section of chip comes in contact with the air, making it possible to form a structure for taking out signals, having excellent bonding properties.

The production method may include, before the step of the forming of the interlayer insulating layer, a step of forming a silicon conductive layer, which is etched at a rate different from that of the interlayer insulating layer, and the removing step involves a step of selectively removing the interlayer insulating layer with the silicon conductive layer as a stopper.

In accordance with the production method, the interlayer insulating layer can be safely removed without adding any new steps merely by changing the mask pattern during the patterning of the silicon conductive layer such as polycrystalline silicon layer constituting the electrode such as gate electrode and charge transferring electrode.

The production method may include, before the step of the forming of the interlayer insulating layer, a step of forming a non-doped insulating layer, which is etched at a rate different from that of the interlayer insulating layer, and the removing step involves a step of selectively removing the interlayer insulating layer with the non-doped insulating layer as a stopper.

In the production method, a formation of a pattern of the wiring layer may be followed by a step of forming a protective layer in such a manner that the pattern of the wiring layer is covered at least at the edge portion of the semiconductor substrate.

In the accordance with the production method, the periphery of the pattern of the wiring layer is surrounded by the underlayer and the protective layer, making it possible to form a semiconductor device having a higher reliability.

In the production method, during the production of a solid imaging element including a photoelectric conversion portion and a charge transferring portion having a charge transferring electrode for transferring charge generated in the photoelectric conversion portion, the charge transferring portion being formed by a first layer electrode of a first layer conductive layer and a second layer electrode of a second layer conductive layer provided in contact with the first layer electrode with an interelectrode insulating layer interposed therebetween, the step of patterning the second layer electrode includes patterning in such a manner that the first conductive layer or second conductive layer is left on the edge portion of the semiconductor substrate as an underlayer.

In accordance with the production method, a solid imaging element having a high reliability can be provided without adding any new steps merely by changing the mask for patterning of the second conductive layer.

In the production method, during the production of a solid imaging element including a photoelectric conversion portion and a charge transferring portion having a charge transferring electrode for transferring charge generated in the photoelectric conversion portion, the charge transferring portion being formed by a first layer electrode of a first conductive layer and a second layer electrode of a second conductive layer provided in contact with the first layer electrode with an interelectrode insulating layer interposed therebetween, the formation of the second layer electrode is preceded by a step of forming a non-doped insulating layer extending to the edge portion of the semiconductor substrate to constitute the underlayer.

The production method may include: a step of forming a plurality of solid imaging elements on the surface of the semiconductor substrate; a step of connecting light-transmitting members to the surface of the semiconductor substrate in such an arrangement that the respective light-transmitting members are spaced from the respective light-receiving regions of the solid imaging elements; a step of dicing the semiconductor substrate in such an arrangement that the wiring layer on the semiconductor substrate is partly exposed at the side surface of the semiconductor substrate; a step of forming an external connecting terminal to the side surface of the semiconductor substrate in correspondence to the solid imaging elements; and a step of separating the connected product formed in the connecting step and having an external connecting terminal on the respective solid imaging elements into respective solid imaging elements.

In accordance with the production method, all the elements are positioned on wafer level and then mounted and integrated altogether before being separated every solid imaging element, making it easy to form a solid imaging element having a high reliability.

In accordance with an aspect of the invention, an interlayer insulating layer such as BPSG layer that causes the occurrence of abnormality can be removed without affecting the device, making it possible to prevent the occurrence of short-circuiting due to penetration of water content and hence enhance the reliability of the device. Further, the formation of difference in level due to wiring can be eliminated, making it possible to inhibit the occurrence of unevenness in resist coating at the subsequent step.

In accordance with another aspect of the invention, an underlayer having etching selectivity with respect to the interlayer insulating layer containing impurities is formed under the wiring layer at the portion for taking out signals of the semiconductor substrate. Thus, the interlayer insulating layer can be removed from this region with the underlayer as an etching stopper, making it possible to design such that the distance between the interlayer insulating layer such as BPSG layer that causes the occurrence of abnormalities and the wiring layer is not smaller than a predetermined value. In this arrangement, short-circuiting due to penetration of water content can be prevented, making it possible to enhance the reliability of the semiconductor device. Further, the formation of difference in level due to wiring can be eliminated, making it possible to inhibit the occurrence of unevenness in resist coating at the subsequent step.

Further, in accordance with a method of an aspect of the invention, a solid imaging element having a high reliability can be formed without requiring any new step merely by changing the pattern.

### BRIEF DESCRIPTION OF THE DRWINGS

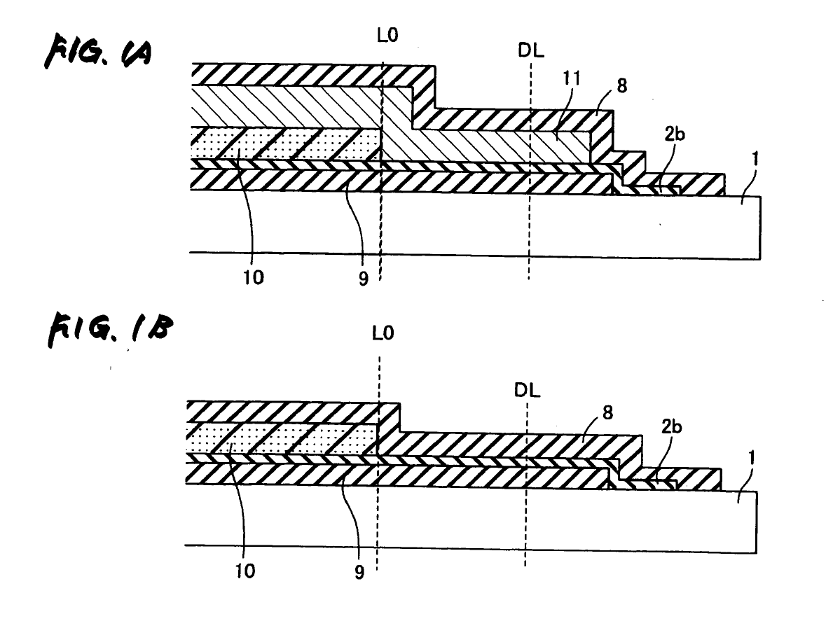

FIGS. 1A and 1B are diagrams of main part illustrating a solid imaging element according to an exemplary embodiment 1 of the invention.

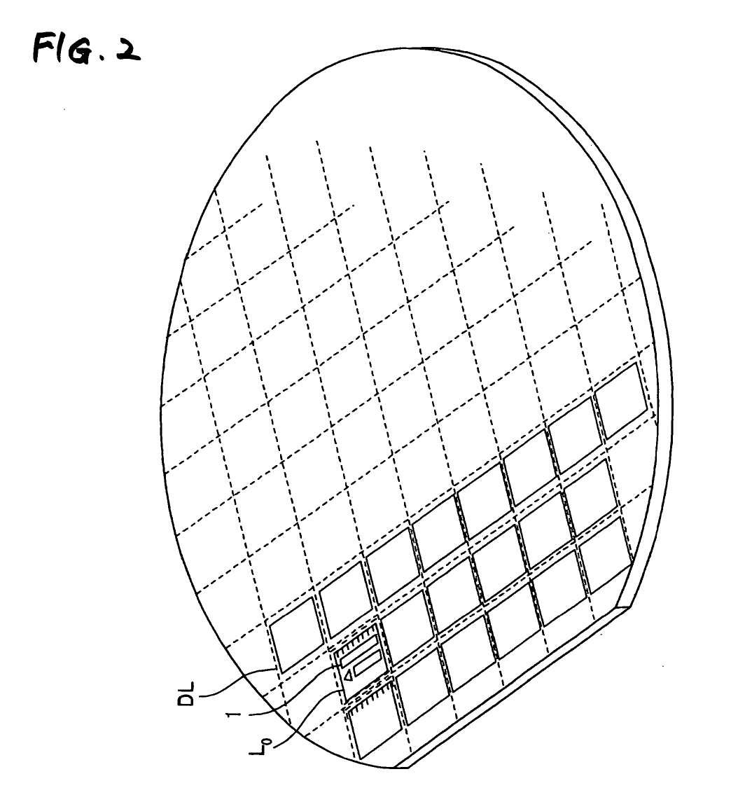

FIG. 2 is a perspective view illustrating a wafer having the solid imaging element according to exemplary embodiments of the invention.

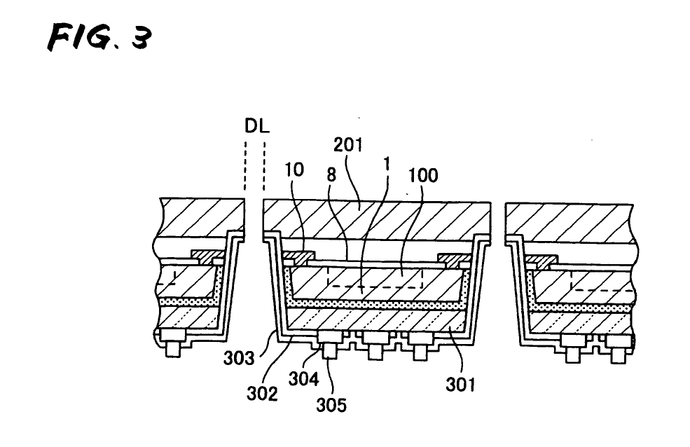

FIG. 3 is a diagram illustrating the mounting structure of the solid imaging element according to exemplary embodiments of the invention.

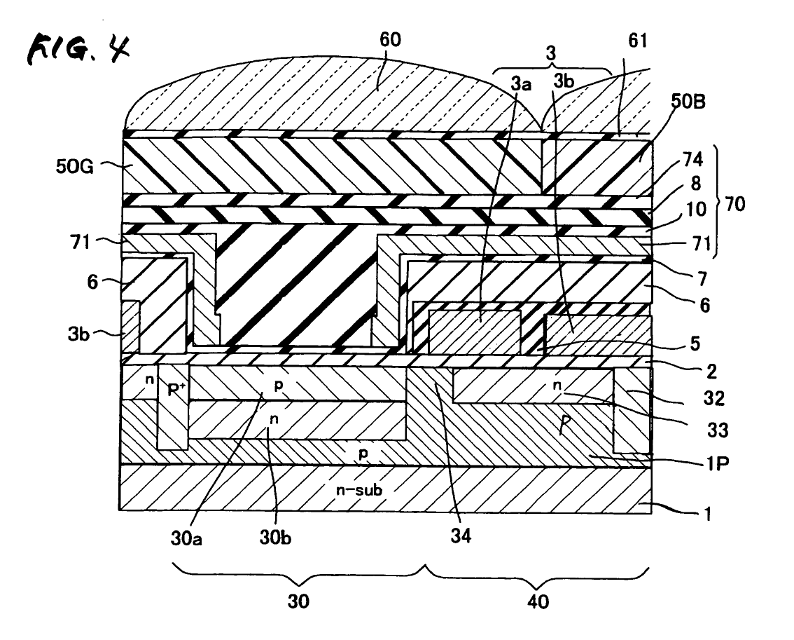

FIG. 4 is a sectional view of main part illustrating the solid imaging element according to an exemplary embodiment 1 of the invention.

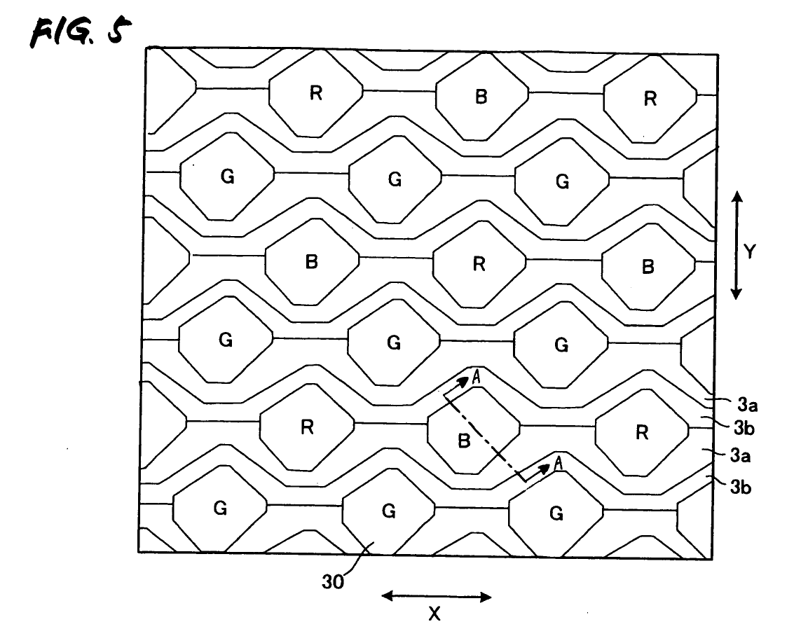

FIG. 5 is a plan view of main part illustrating the solid imaging element according to exemplary embodiments of the invention.

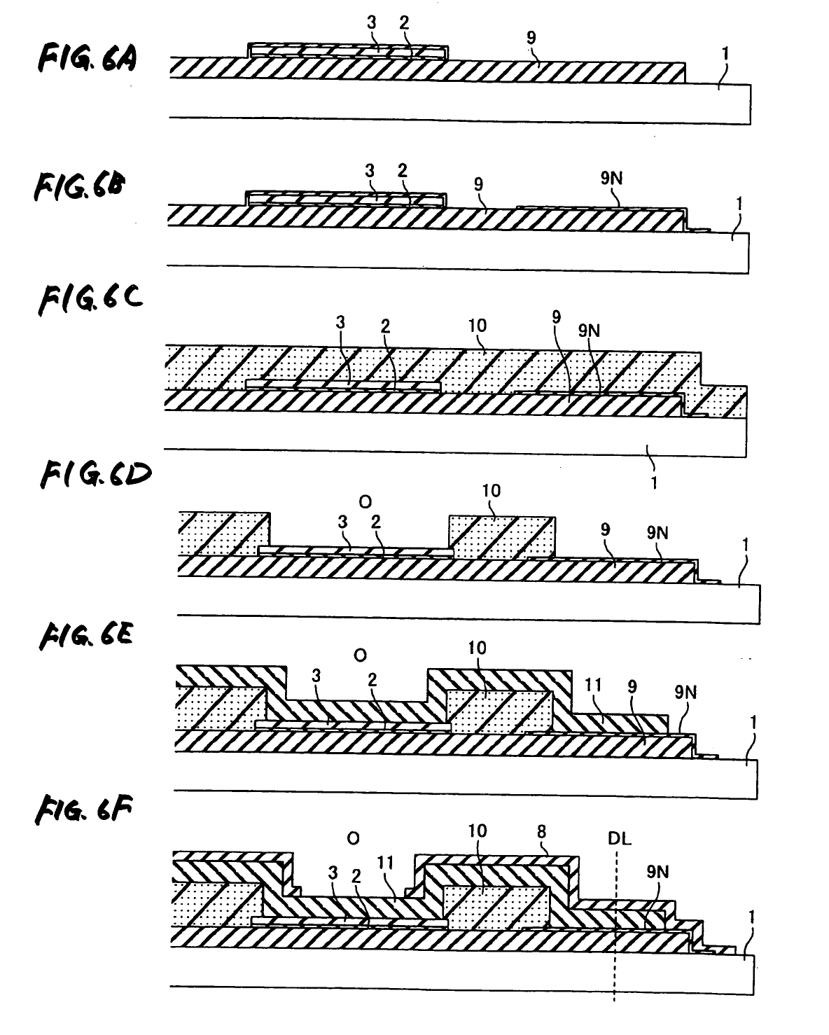

FIGS. 6A to 6F are sectional views illustrating a process for the production of the solid imaging element according to an exemplary embodiment 1 of the invention.

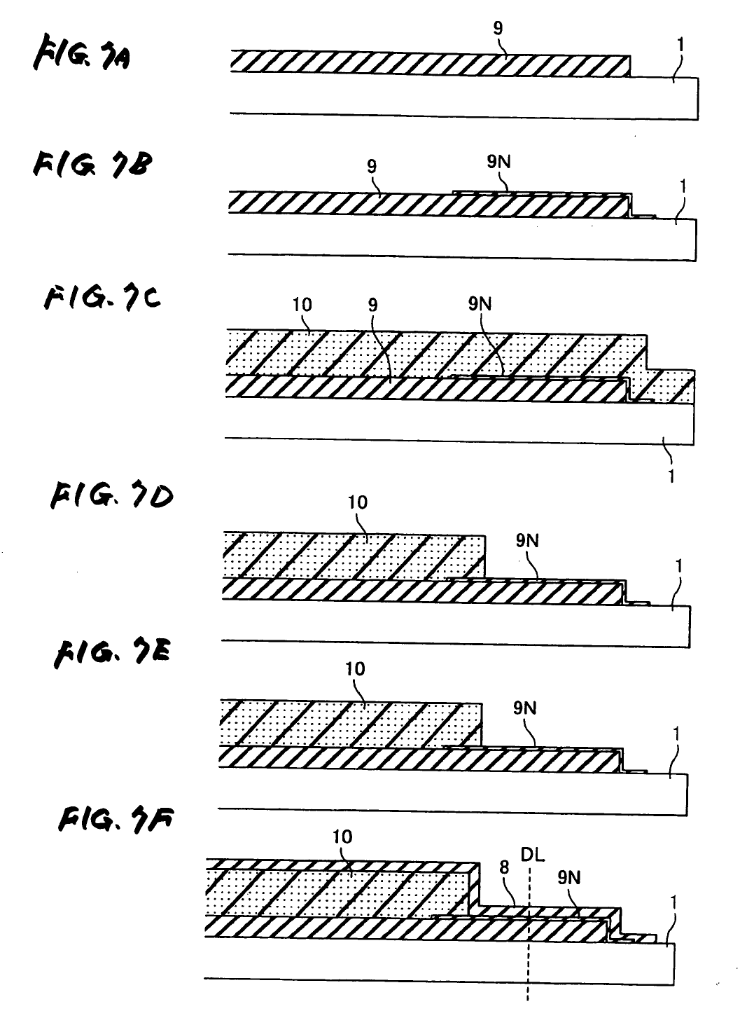

FIGS. 7A to 7F are sectional views illustrating a process for the production of the solid imaging element according to an exemplary embodiment 1 of the invention.

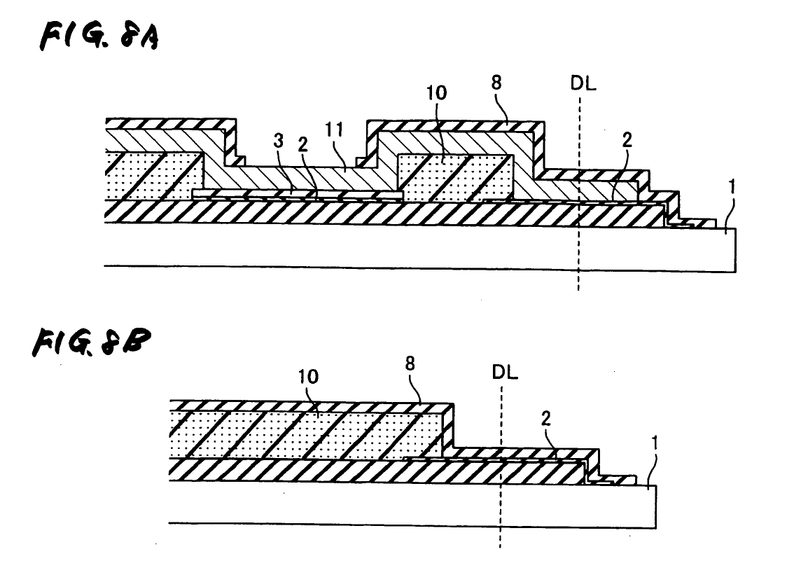

FIGS. 8A and 8B are sectional view illustrating a solid imaging element according to an exemplary embodiment 2 of the invention.

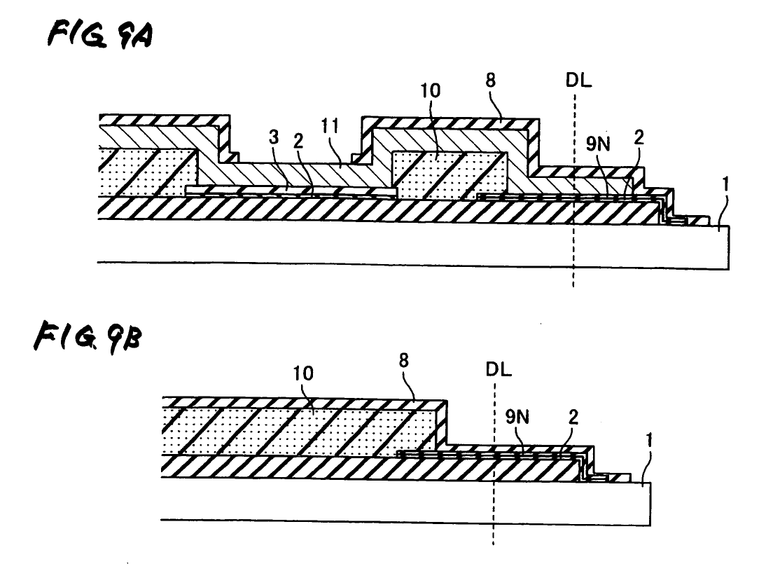

FIGS. 9A and 9B are sectional views illustrating a solid imaging element according to an exemplary embodiment 3 of the invention.

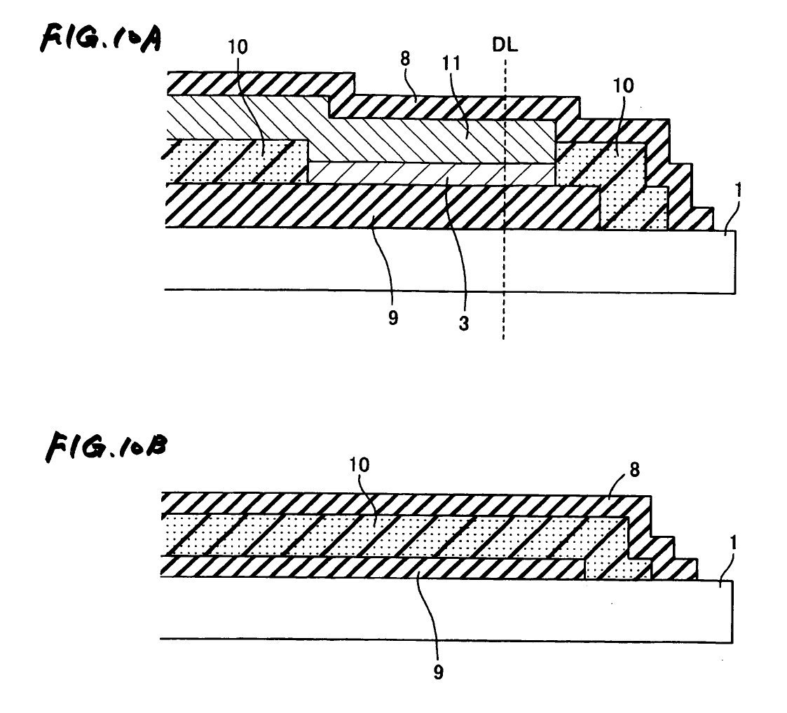

FIGS. 10A and 10B are diagrams of main part illustrating a solid imaging element according to an exemplary embodiment 4 of the invention.

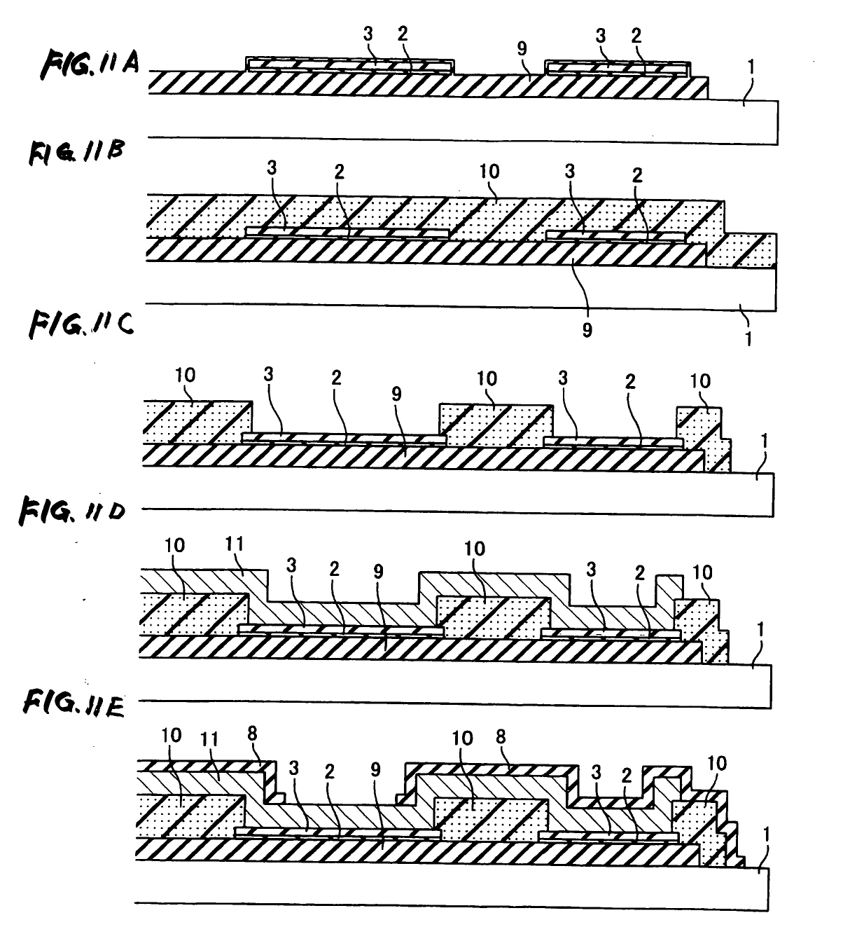

FIGS. 11A to 11E are sectional view illustrating a process for the production of the solid imaging element according to an exemplary embodiment 4 of the invention.

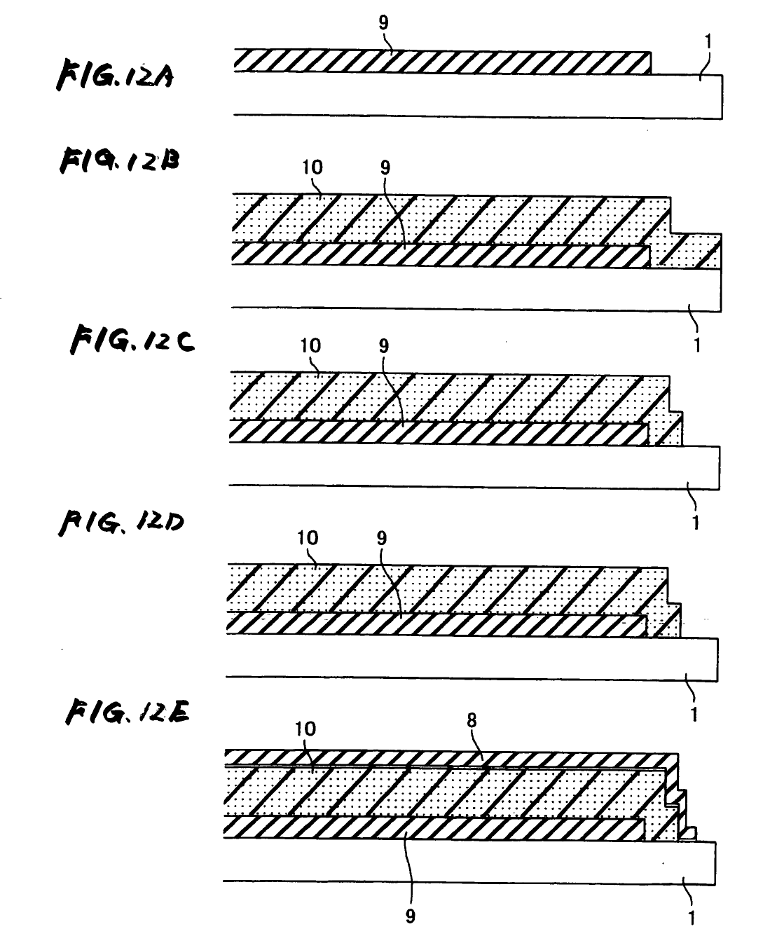

FIGS. 12A to 12E are sectional view illustrating a process for the production of the solid imaging element according to an exemplary embodiment 4 of the invention.

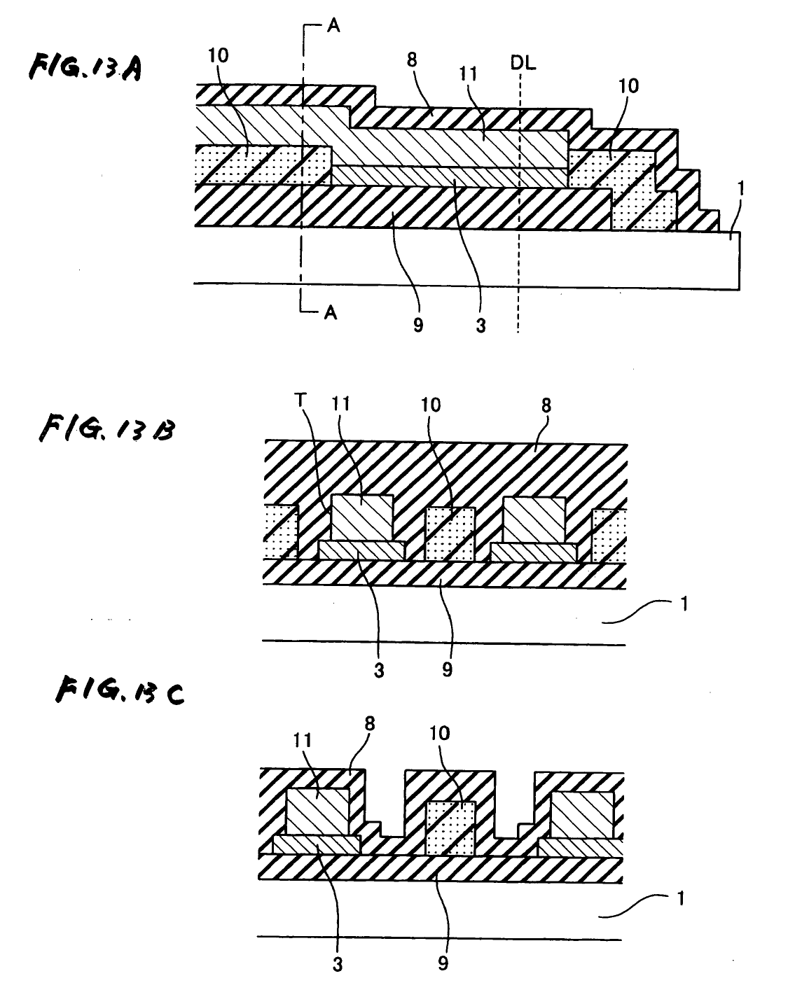

FIGS. 13A to 13C are sectional views illustrating a solid imaging element according to an exemplary embodiment 5 of the invention.

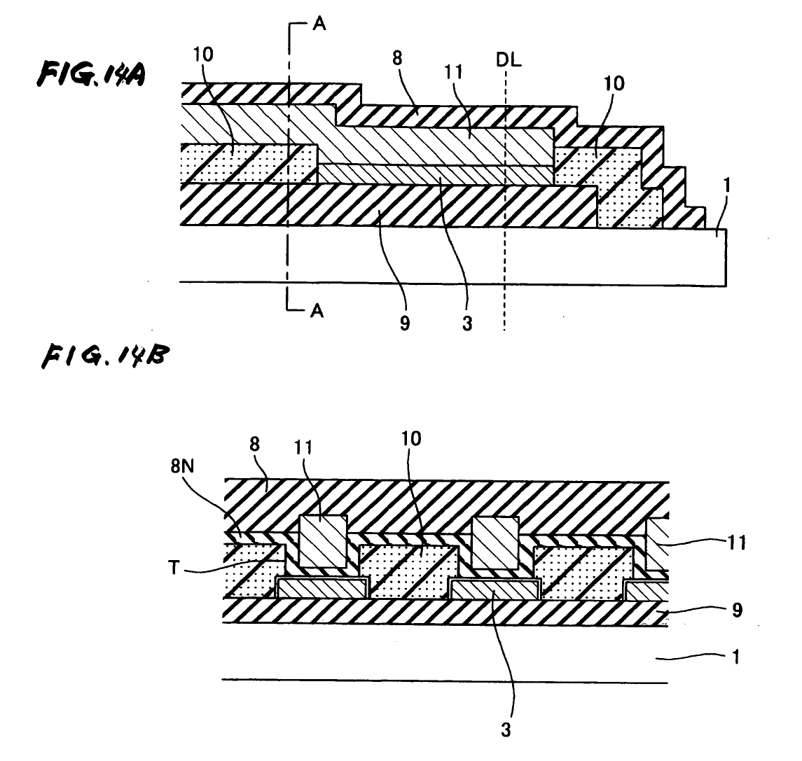

FIGS. 14A and 14B are sectional views illustrating a solid imaging element according to an exemplary embodiment 6 of the invention.

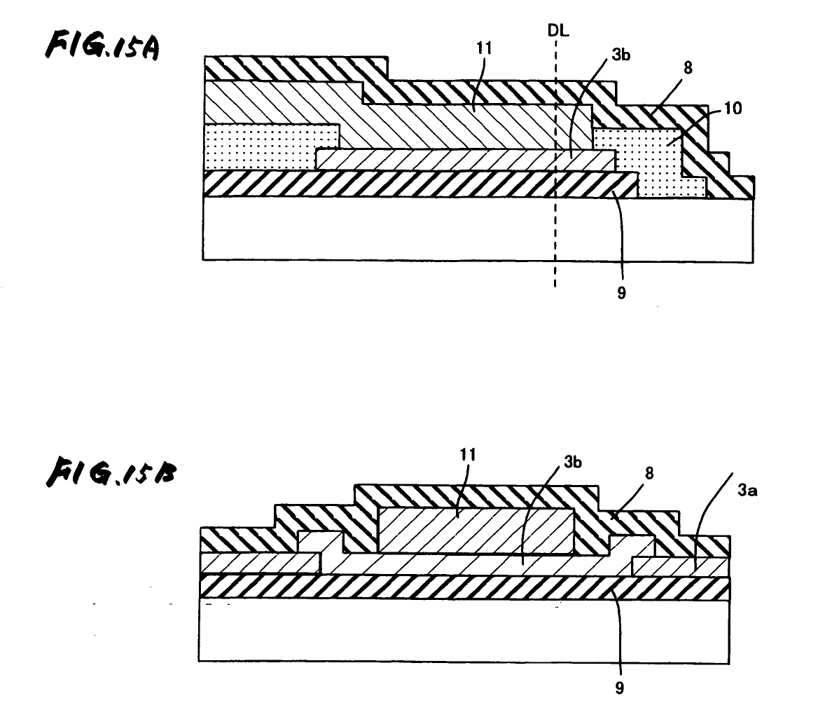

FIGS. 15A and 15B are sectional views illustrating a solid imaging element according to an exemplary embodiment 7 of the invention.

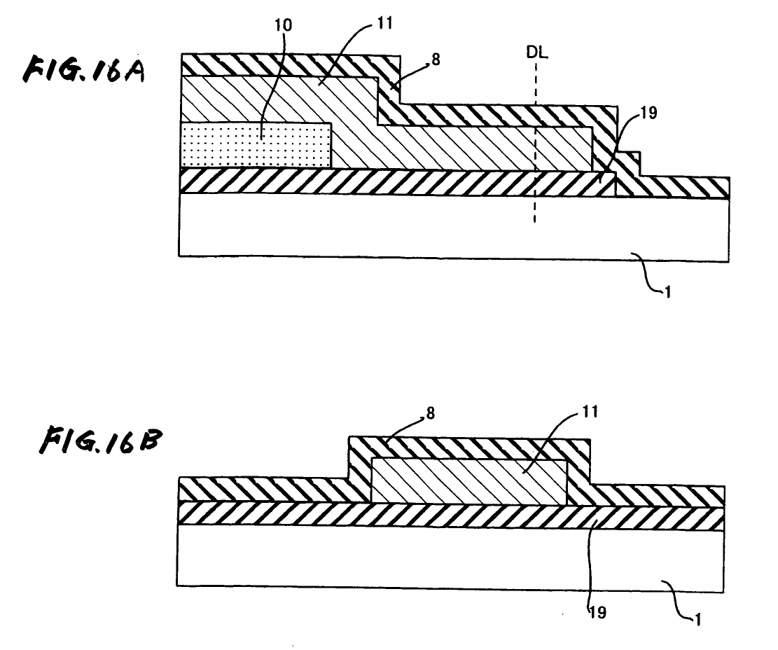

FIGS. 16A and 16B are sectional views illustrating a solid imaging element according to an exemplary embodiment 8 of the invention.

FIGS. 17A and 17B are diagrams of main part of a solid imaging element in the background art.

### DETAILED DESCRIPTION OF THE INVENTION

Exemplary embodiments of the invention will be described hereinafter in connection with the attached drawings.

### EMBODIMENT 1

An example of a solid imaging element to which a structure for taking out signals in a semiconductor device of an exemplary embodiment of the invention is applied will be first described. As shown in the sectional view of FIGS. 1A and 1B, this solid imaging element is characterized by the end surface of the wiring structure formed on the surface of the silicon substrate 1 having a photoelectric conversion portion (photodiode) and a charge transferring portion formed thereon. BPSG layer 10 (interlayer insulating layer) as a reflow layer for leveling formed under an aluminum wiring layer 11 has been removed over the region ranging from the level sufficiently inside the dicing line to the edge. The structure may be as it is on the periphery (portion) free of wiring. In the present embodiment, however, the interlayer insulating layer has been removed over the entire periphery of the silicon substrate (chip) 1. These layers are covered by a protective layer 8 composed of a silicon nitride layer formed by plasma CVD method. FIG. 1A depicts the sectional view of a wiring portion. FIG. 1B depicts the sectional view of a wiring-free portion. As shown in the illustration of a semiconductor wafer which is ready to be divided into chips in FIG. 2, BPSG layer 10 as an interlayer insulating layer has been removed over the region ranging from the dicing line DL to the line L0.

In this arrangement, the short-circuiting of wiring due to impurity ions in BPSG layer 10 or deterioration of the aluminum wiring layer due to acid produced by the reaction of these impurity ions with water content taken in by themselves can be prevented. Further, this arrangement can not only enhance the reliability of the wiring but also prevent the occurrence of difference in level due to the rise of the peripheral portion, making it possible to eliminate unevenness in coating due to difference in level also during the spreading of the color filter coating solution.

This solid imaging element is formed in such an arrangement that it is cut at the dicing line DL to cause the aluminum wiring layer to be exposed at the side, i.e., cut surface on which signals is taken out.

Mounting is made on the level of wafer which is then divided. In this manner, a CSP structure can be formed. FIG. 3 is a schematic diagram illustrating a mounted structure including this solid imaging element. In this arrangement, a sealing cover glass 201 is formed opposed to the light-receiving region in the solid imaging element 100 formed on the silicon substrate 1. Further, a rear cover glass 301 having a wiring pattern formed on the back side thereof is formed. Thus, a moistureproof structure is established.

In some detail, the glass substrate 201 as a light-transmitting member constituting a sealing cover glass is connected to the surface of a solid imaging element including the silicon substrate 1 as a semiconductor substrate having the solid imaging element 100 formed thereon with a spacer (not shown) provided interposed therebetween in such an arrangement that a clearance is formed opposed to the light-receiving region in the solid imaging element. These elements are connected on wafer level so that a plurality of elements are mounted altogether. The peripheral edge of the silicon substrate 1 is individually separated by dicing. In this manner, electrical connection is made by a wiring lead 302 formed on a bump 305 extending over the area ranging from the side wall of the silicon substrate to the side of the rear cover glass 301 via a bonding pad 304 formed on the back surface of the silicon substrate. The device thus formed is then surface-mounted on a mounting substrate with the bump 305. The reference numeral 303 indicates a passivation layer.

In the present embodiment, the solid imaging element, though having an ordinary structure in other embodiments, includes a silicon substrate 1 having solid imaging elements aligned thereon and RGB color filters 50 (50G, 50B, 50R) and a microlens 60 formed thereon as shown in an enlarged sectional view of main part of imaging region of FIG. 4 and plan view of FIG. 5.

On the surface of an n-type silicon substrate 1 are formed aligned photodiodes 30 which constitutes a photoelectric conversion portion. A charge-transferring portion 40 for transferring signal charge generated in the various photodiodes 30 in the column direction (Y direction in FIG. 5) is formed zigzag between a plurality of photodiode columns of photodiode 30 provided aligned in the column direction. The odd columns of photodiode and the even columns of photodiode are disposed in such an arrangement that the photodiodes 30 of the two columns deviate in the column direction from each other by about half the pitch of photodiodes.

The charge transferring portion 40 comprises a plurality of charge transferring channels 33 formed in the column direction on the surface of the silicon substrate 1 for each of the plurality of photodiode columns, charge transferring electrodes 3 (first layer electrode 3a, second layer electrode 3b) formed above the charge transferring channels 33 and charge reading regions 34 for reading charge generated in the photodiodes 30 to the charge transferring channels 33. The charge transferring electrodes 3 each generally extend zigzag in the row direction (X direction in FIG. 5) between a plurality of rows of photodiodes 30 aligned in the row direction. While the present embodiment is described with reference to the case the charge transferring electrodes 3 each are a single-layer electrode structure obtained by forming a second layer electrode on a first layer electrode with an interelectrode insulating layer interposed therebetween, and then leveling the second layer electrode by CMP, the invention is not limited to the single-layer electrode structure. The charge transferring electrodes 3 each may be a two-layer electrode structure including a first layer electrode part of which is covered by a second layer electrode.

As shown in FIG. 4, the silicon substrate 1 has a p-well layer 1P formed on the surface thereof The p-well layer 1P has an n-region 30b forming a pn junction formed therein and a p-region 30a formed on the surface thereof to constitute a photodiode 30. The signal charge generated in the photodiode 30 is stored in the n-region 30b.

Formed somewhat apart rightward from the photodiode 30 is the charge transferring channel 33 including n-region. In the p-well layer 1P formed between the n region 30b and the charge transferring channel 33 is formed the charge reading region 34.

The silicon substrate 1 also has a gate oxide layer 2 formed on the surface thereof A first electrode 3a and a second electrode 3b are formed on the charge reading region 34 and the charge transferring channel 33 with the gate oxide layer 2 interposed therebetween. Formed interposed between the first electrode 3a and the second electrode 3b is an interelectrode insulating layer 5. Formed at the right side of the vertical transferring channel 33 is a channel stop 32 composed of p+ region that separates the photodiode 30 from the adjacent photodiode 30.

Formed over the charge transferring electrode 3 are an insulating layer 6 such as silicon oxide layer and an anti-reflection layer 7 over which interlayers 70 are formed. Among the interlayers 70 are a light-shielding layer 71, an interlayer insulating layer 10 composed of BPSG (borophospho silicate glass), an insulating layer (passivation layer) 8 composed of P—SiN and a leveling layer under filter 74 composed of transparent resin or the like. The light-shielding layer 71 is provided except at the opening portion of the photodiode 30. Formed above the interlayers 70 are a color filter and a microlens 60. Formed interposed between the color filter 50 and the microlens 60 is a leveling layer over filter 61 composed of insulating transparent resin or the like.

The solid imaging element according to the present embodiment is arranged such that signal charge generated in the photodiode 30 is stored in the n region 30b, the signal charge stored in the n region 30b is transferred in the column direction through the charge transferring channel 33, the signal charge thus transferred is transferred in the row direction through a horizontal charge transferring channel (HCCD) which is not shown and a color signal corresponding to the signal charge thus transferred is outputted from an amplifier which is not shown. In some detail, a solid imaging element portion which is a region including a photoelectric conversion portion, a charge transferring portion, HCCD and an amplifier and a peripheral circuit portion which is a region having a peripheral circuit of solid imaging element (PDA portion, etc.) formed therein are formed on the silicon substrate 1 to constitute a solid imaging element.

A process for the production of the solid imaging device will be described below. Firstly, a process for the production of the solid imaging element will be described. The photoelectric conversion portion and the charge transferring electrode of the solid imaging element are formed by an ordinary method. The present embodiment is characterized by the formation of the wiring layer, particularly the edge portion of the substrate. Therefore, description will be made focusing on the edge portion of the substrate. FIGS. 6A to 6F each are a sectional view of the wiring portion. FIGS. 7A to 7F each are a sectional view of the wiring-free portion. FIGS. 6A to 6F and FIGS. 7A to 7F correspond to each other, respectively.

Firstly, an n-type silicon substrate 1 is prepared. A field oxide layer 9 is then formed on the n-type silicon substrate 1. A gate oxide layer 2 is also formed on the surface of the n-type silicon substrate 1 having a charge transferring channel, a channel stop region and a charge reading region formed therein.

Subsequently, a charge transferring electrode composed of a phosphorus-doped amorphous silicon layer 3, a peripheral circuit wiring and an evaluation pad are formed on the gate oxide layer 2. Though not shown, the substrate is patterned in the central portion thereof for charge transferring electrode (FIG. 6A, FIG. 7A). An insulating layer such as silicon oxide layer and silicon nitride layer is then formed on the charge transferring electrode by an ordinary method. During this procedure, a silicon nitride layer 9N is left on the outer edge of the field insulating layer 9 on the edge portion of the substrate (FIG. 6B, FIG. 7B). As the silicon nitride layer 9N there may be used an anti-reflection layer left on the edge portion of the substrate.

Subsequently, TiN layer as an adhesive layer and a light-shielding layer (not shown: W layer) are sequentially formed on these layers.

Subsequently, a resist is spread over the light-shielding layer which is then subjected to photolithography so that it is patterned.

Subsequently, BPSG layer 10 is deposited on these layers by CVD method. BPSG layer 10 is then subjected to reflow for leveling (FIG. 6C, FIG. 7C). Subsequently, the laminate is optionally subjected to reflow by heat treatment at a temperature as high as 800° C. to 900° C. so that it is leveled. Thereafter, the substrate is subjected to photolithography at the edge portion thereof so that BPSG layer 10 is patterned (FIG. 6D, FIG. 7D). During this procedure, an opening O in which an evaluation pad is to be formed is formed. In the present embodiment, the silicon nitride layer 9N is used as an etching stop layer.

In order to form an optical waveguide structure, the opening O may be formed at the same time at an etching step of forming a columnar high refractive index material layer as optical waveguide.

Subsequently, a wiring layer 11 composed of aluminum layer is formed on these layers (FIG. 6E, FIG. 7E). Subsequently, a silicon nitride layer 8 is formed on these layers as a protective layer by plasma CVD method in such an arrangement that it covers the edge of the wiring layer 11 at the edge portion of the substrate (FIG. 6F, FIG. 7F).

Subsequently, the silicon nitride layer is etched in such a manner that the aluminum layer in the region for bonding pad is exposed. After an opening is formed, the substrate is then subjected to sintering in an inert gas atmosphere containing hydrogen to form a leveling layer 74 (under filter) composed of transparent resin layer (see FIG. 4).

In this manner, mounting is made according to a so-called wafer level CSP method which comprises positioning a silicon wafer having solid imaging elements formed therein on wafer level, mounting all the elements altogether to form an integral body, and then subjecting the silicon wafer to dicing so that it is divided every solid imaging element along the dicing line DL (see FIG. 3).

Thus, a solid imaging device can be formed extremely easily at a good working efficiency. As mentioned above, in accordance with the invention, the elements are positioned on wafer level, mounted altogether to form an integral body which is then divided every solid imaging element. Accordingly, a solid imaging device having a high reliability can be easily produced. Further, individual solid imaging devices can be formed merely by separating or grinding the silicon wafer while the surface on which the elements are formed is being sealed in the gap by connection, making it possible to provide a solid imaging device having a high reliability with little damage to the elements and no risk of contamination by dust.

While the present embodiment has been described with reference to the case where BPSG layer has been removed over the entire edge of the substrate, it is not necessarily required to remove BPSG layer over the entire edge of the substrate. The interlayer insulating layer may be removed only at the edge portion where short-circuiting cannot occur.

### EMBODIMENT 2

An exemplary embodiment 2 of the invention will be described hereinafter. The present embodiment is characterized by the use of an ONO layer 2 which is a gate oxide layer as an etching stopper during the patterning of BPSG layer 10 as shown in FIG. 8. The present embodiment is the same as the embodiment 1 with respect to the other portions.

In this arrangement, too, a solid imaging device having a high reliability can be formed without requiring any addition steps merely by changing the pattern.

### EMBODIMENT 3

An exemplary embodiment 3 of the invention will be described hereinafter. The present embodiment is characterized by the use of a laminated structure including an ONO layer 2 as a gate oxide layer and a silicon nitride layer 9N formed at the same step as that for anti-reflection layer as an etching stopper during the patterning of BPSG layer 10 as shown in FIG. 9. The present embodiment is the same as the embodiment 1 with respect to the other portions.

In this arrangement, too, a solid imaging device having a high reliability can be formed without requiring any addition steps merely by changing the pattern.

### EMBODIMENT 4

As shown in the sectional view of FIGS. 10A and 10B, a solid imaging element of an exemplary embodiment 4 of the invention is characterized by the end surface of the wiring structure formed on the surface of the silicon substrate 1 having a photoelectric conversion portion (photodiode) and a charge transferring portion formed thereon. At the edge portion of the semiconductor substrate, a polycrystalline silicon layer 3 as an underlayer having etching selectivity with respect to the interlayer insulating layer (BPSG layer) as a reflow layer for leveling is formed. In this region, the interlayer insulating layer 10 is selectively removed. In the edge region of the semiconductor substrate free of wiring layer 11, BPSG layer is left formed as it is. These layers are covered by a protective layer 8 including a silicon nitride layer formed by plasma CVD method. FIG. 1A depicts the sectional view of a wiring portion. FIG. 1B depicts the sectional view of a wiring-free portion. As shown in the illustration of a semiconductor wafer which is ready to be divided into chips in FIG. 2, in the region where the wiring layer is present on the dicing line DL within the region ranging from the dicing line DL to the line L0, a polycrystalline silicon layer (pad for taking out signals) 3 is formed as an underlayer and BPSG layer 10 as interlayer insulating layer has been removed.

In this arrangement, the short-circuiting of wiring due to impurity ions in BPSG layer 10 or deterioration of the aluminum wiring layer due to acid produced by the reaction of these impurity ions with water content taken in by themselves can be prevented. Further, this arrangement can not only enhance the reliability of the wiring but also prevent the occurrence of difference in level due to the rise of the peripheral portion, making it possible to eliminate unevenness in coating due to difference in level also during the spreading of the color filter coating solution.

This solid imaging element is formed in such an arrangement that it is cut at the dicing line DL to cause the aluminum wiring layer to be exposed at the side, i.e., cut surface on which signals is taken out. In this case, the region corresponding to the thickness of the two layers, i.e., polycrystalline silicon layer and aluminum wiring layer means the contact area with the wiring lead. In this arrangement, good contact properties can be obtained.

Mounting is made on the level of wafer which is then divided. In this manner, a CSP structure can be formed. A solid imaging element substrate has a similar structure to that of the embodiment 1 as shown in FIGS. 4 and 5.

A process for the production of the solid imaging device will be described below. Firstly, a process for the production of the solid imaging element will be described. The photoelectric conversion portion and the charge transferring electrode of the solid imaging element are formed by an ordinary method. The present embodiment is characterized by the formation of the wiring layer, particularly the edge portion of the substrate. Therefore, description will be made focusing on the edge portion of the substrate. FIGS. 11A to 11E each are a sectional view of the wiring portion. FIGS. 12A to 12E each are a sectional view of the wiring-free portion. FIGS. 11A to 11E and FIGS. 12A to 12E correspond to each other, respectively.

Firstly, an n-type silicon substrate 1 is prepared. A field oxide layer 9 is then formed on the n-type silicon substrate 1. A gate oxide layer 2 is also formed on the surface of the n-type silicon substrate 1 having a charge transferring channel, a channel stop region and a charge reading region formed therein. In the present embodiment, as a gate oxide layer there is used a three-layer structure including a silicon oxide layer, a silicon nitride layer and a silicon oxide layer.

Subsequently, a phosphorus-coped polycrystalline silicon layer 3 is deposited on the gate oxide layer 2. The phosphorus-coped polycrystalline silicon layer 3 is then subjected to photolithography to form a wiring of charge transferring electrode and peripheral circuit and a pad 3 for taking out signals. Though not shown, in the central part of the substrate, the formation of a first layer phosphorus-doped polycrystalline silicon layer 3, a patterning step, the formation of a second layer phosphorus-doped polycrystalline silicon layer 3, CMP and a patterning step involving photolithography are effected before patterning of charge transferring electrode. At any of these steps, patterning is effected such that the phosphorus-doped polycrystalline silicon layer 3 is left also in the vicinity of the dicing line DL (FIGS. 11A and 12A). Subsequently, an insulating layer such as silicon oxide layer and silicon nitride layer is formed on the charge transferring electrode by an ordinary method.

Subsequently, TiN layer as an adhesive layer and W layer as a light-shielding layer (as shown in FIG. 4, “71”) are sequentially formed on these layers.

Subsequently, a resist is spread over the light-shielding layer which is then subjected to photolithography so that it is patterned.

Subsequently, BPSG layer 10 is deposited on these layers by CVD method. BPSG layer 10 is then subjected to reflow for leveling (FIGS. 11B and 12B). Subsequently, the laminate is optionally subjected to reflow by heat treatment at a temperature as high as 800° C. to 900° C. so that it is leveled. Thereafter, the substrate is subjected to photolithography at the edge portion thereof so that BPSG layer 10 is patterned (FIGS. 11C and 12C). During this procedure, an opening O in which an evaluation pad is to be formed is formed. At the same time, the interlayer insulating layer under the wiring layer is removed. In the present embodiment, the polycrystalline silicon layer 3 is used as an etching stop layer.

In order to form an optical waveguide structure, the opening O may be formed at the same time at an etching step of forming a columnar high refractive index material layer as optical waveguide.

Subsequently, a wiring layer 11 composed of aluminum layer is formed on these layers (FIGS. 11D and 12D). Subsequently, a silicon nitride layer 8 is formed on these layers as a protective layer by plasma CVD method in such an arrangement that it covers the edge of the wiring layer 11 at the edge portion of the substrate (FIGS. 11E and 12E).

Subsequently, the silicon nitride layer is etched in such a manner that the aluminum layer in the region for bonding pad is exposed. After an opening is formed, the substrate is then subjected to sintering in an inert gas atmosphere containing hydrogen to form a leveling layer 74 (under filter) composed of transparent resin layer (see FIG. 4).

In this manner, mounting is made according to a so-called wafer level CSP method which comprises positioning a silicon wafer having solid imaging elements formed therein on wafer level, mounting all the elements altogether to form an integral body, and then subjecting the silicon wafer to dicing so that it is divided every solid imaging element along the dicing line DL (see FIG. 3).

Thus, a solid imaging device can be formed extremely easily at a good working efficiency. As mentioned above, in accordance with the invention, the elements are positioned on wafer level, mounted altogether to form an integral body which is then divided every solid imaging element. Accordingly, a solid imaging device having a high reliability can be easily produced. Further, individual solid imaging devices can be formed merely by separating or grinding the silicon wafer while the surface on which the elements are formed is being sealed in the gap by connection, making it possible to provide a solid imaging device having a high reliability with little damage to the elements and no risk of contamination by dust.

### EMBODIMENT 5

An exemplary embodiment 5 of the invention will be described hereinafter. The present embodiment is characterized by the patterning of BPSG layer 10 involving the selective removal of BPSG layer 10 with the underlayer polycrystalline silicon layer 3 left somewhat wider than the pattern of the wiring layer as an etching stopper in correspondence to the pattern of the wiring layer in the dicing region leading to the formation of recessed portions T which are slightly greater than the pattern of the wiring layer 11, in which recessed portions the wiring layer 11 is embedded, as shown in FIGS. 13A and 13B. Subsequently, a silicon nitride 8 is formed as a passivation layer. During this procedure, the silicon nitride layer 8 is formed also on the side wall of the pattern of the wiring layer 11. In this arrangement, the periphery of the wiring layer 11 is surrounded by the silicon nitride layer 8. FIG. 13B is a sectional view taken along the line A-A of FIG. 13A.

In this arrangement, the surface of the edge portion of the semiconductor substrate can be leveled. Further, in the region for taking out signals, the layer under the wiring layer is a polycrystalline silicon layer the side wall of which is covered by a dense insulating layer (silicon nitride layer) formed by CVD method instead of BPSG layer, making it possible to prevent the penetration of water content from BPSG.

While the present embodiment has been described with reference to the case where the passivation layer is formed to a sufficient thickness so that the silicon nitride layer can be sufficiently embedded in the space in the side wall of the pattern of the wiring layer 11, the silicon nitride layer may be formed in such an arrangement that it covers the side wall of the wiring layer 11 to form roughness on the surface thereof as shown in FIG. 13C.

### EMBODIMENT 5

An exemplary embodiment 5 of the invention will be described hereinafter. As shown in FIGS. 14A and 14B, the present embodiment is characterized by the patterning of BPSG layer 10 involving the formation of recessed portions T corresponding to the pattern of wiring layer in the dicing region followed by the formation of a two-layer layer 8N including a radical oxide layer and a silicon nitride layer formed by CVD method in the recessed portions T followed by the formation of the wiring layer 11 thereon. FIG. 14B is a sectional view taken along the line A-A of FIG. 14A. In this arrangement, in the region for taking out signals, the periphery of the wiring layer is covered by a dense two-layer insulating layer, making it possible to prevent the penetration of water content from BPSG.

### EMBODIMENT 7

An exemplary embodiment 7 the invention will be described hereinafter. As shown in FIGS. 15A and 15B, the present embodiment is characterized by a process which comprises patterning doped amorphous silicon layers 3a and 3b as first layer electrode and second layer electrode constituting the charge transferring electrode of solid imaging element in such a manner that these layers are left also in the vicinity of the dicing region, i.e., edge portion of substrate, followed by the patterning of BPSG layer 10 during which BPSG layer 10 is selectively removed from the dicing region with the underlayer polycrystalline silicon layer 3 left somewhat wider than the pattern of wiring layer as an etching stopper to form a pattern of the wiring layer 11. Subsequently, a silicon nitride layer 8 is formed as a passivation layer in such a manner that it surrounds the pattern of the wiring layer 11. During this procedure, the silicon nitride layer 8 is formed also on the side wall of the pattern of the wiring layer 11. In this arrangement, the periphery of the wiring layer 11 is surrounded by the silicon nitride layer 8. FIG. 15B is a sectional view taken along the line A-A of FIG. 15A.

In this arrangement, in the region for taking out singals, the layer under the wiring layer is a polycrystalline silicon layer the side wall of which is covered by a dense insulating layer (silicon nitride layer) formed by CVD method instead of BPSG layer as a passivation layer 8, making it possible to prevent the penetration of water content from BPSG.

### EMBODIMENT 8

An exemplary embodiment 8 the invention will be described hereinafter. As shown in FIGS. 16A and 16B, the present embodiment is characterized by a process which comprises patterning an insulating layer 19 such as non-doped silicon oxide layer in such a manner that the insulating layer 19 is left also in the vicinity of the dicing region, i.e., edge portion of substrate, followed by the patterning of BPSG layer 10 during which BPSG layer 10 is selectively removed from the dicing region with the underlayer non-doped silicon oxide layer 19 left somewhat wider than the pattern of wiring layer as an etching stopper to form a pattern of the wiring layer 11. Subsequently, a silicon nitride layer 8 is formed as a passivation layer in such a manner that it surrounds the pattern of the wiring layer 11. During this procedure, the silicon nitride layer 8 is formed also on the side wall of the pattern of the wiring layer 11. In this arrangement, the periphery of the wiring layer 11 is surrounded by the silicon nitride layer 8. FIG. 16B is a sectional view taken along the line A-A of FIG. 16A.

In this arrangement, in the region for taking out signals, the layer under the wiring layer is a non-doped silicon oxide layer 19 the side wall of which is covered by a dense insulating layer (silicon nitride layer) formed by CVD method instead of BPSG layer as a passivation layer 8, making it possible to prevent the penetration of water content from BPSG.

While the aforementioned embodiments have been described with reference to the case where the wiring layer containing a bonding pad is composed of aluminum layer, the invention is not limited to aluminum layer. It goes without saying that the wiring layer may be a layer made of other metals such as gold or other conductors such as silicide.

The method for the formation of the wiring lead may be properly selected from the group consisting of ink jet method, dispensing by dispenser, screen printing and stamping.

While the aforementioned embodiments have been also described with reference to solid imaging element, the invention is not limited to solid imaging element. It goes without saying that the invention can be applied to ordinary semiconductor devices such as LSI constituting logic circuit.

In accordance with the constitution of the invention, the size of semiconductor devices can be reduced. The resulting semiconductor device can be fairly used as a solid imaging element for electronic appliance such as cellular phone. Further, since all the elements are positioned on wafer level and then mounted altogether, including the formation of electrode terminal for taking out signals, to form an integral body which is then divided every element, a semiconductor device having a high reliability can be easily produced.

It will be apparent to those skilled in the art that various modifications and variations can be made to the described embodiments of the invention without departing from the spirit or scope of the invention. Thus, it is intended that the invention cover all modifications and variations of this invention consistent with the scope of the appended claims and their equivalents.

The present application claims foreign priority based on Japanese Patent Application Nos. JP2005-182426, JP2005-197852 and JP2006-3921, filed June 22 of 2005, July 6 of 2005 and January 11 of 2006, respectively, the contents of which is incorporated herein by reference.

1. A semiconductor device comprising:
a semiconductor substrate having an element region;
an interlayer insulating layer containing an impurity; and
a wiring layer for taking out a signal,
wherein at least a portion of the interlayer insulating layer in contact with the wiring layer is removed at least at a part of an edge portion of the semiconductor substrate.

2. The semiconductor device according to claim 1, wherein the interlayer insulating layer is one of a BPSG layer and a PSG layer.

3. The semiconductor device according to claim 1, comprising an insulating layer acting as a stopper under the interlayer insulating layer, wherein the insulating layer acting as a stopper has etching selectivity with respect to the interlayer insulating layer.

4. The semiconductor device according to claim 3, wherein the stopper insulating layer comprises silicon nitride.

5. The semiconductor device according to claim 1, wherein the interlayer insulating layer is removed over the entire edge portion of the semiconductor device.

6. The semiconductor device according to claim 1, wherein the wiring layer is exposed at the edge portion of the semiconductor substrate and is externally connected through a wiring lead provided on a side surface of the semiconductor substrate.

7. The semiconductor device according to claim 1, wherein the wiring layer is a metallic layer.

8. The semiconductor device according to claim 7, wherein the metallic layer comprises one of aluminum and aluminum alloy.

9. The semiconductor device according to claim 1, which is a solid imaging element of a chip size package.

10. A method for producing a semiconductor device comprising: a semiconductor substrate having an element region; an interlayer insulating layer containing an impurity; and a wiring layer for taking out a signal,
the method comprising selectively removing at least a portion of the interlayer insulating layer in contact with the wiring layer at least at a part of an edge portion of the semiconductor substrate.

11. The method for producing a semiconductor device according to claim 10, comprising forming an insulating layer before forming the interlayer insulating layer, wherein the insulating layer formed before forming the interlayer insulating layer has a different etching rate from the interlayer insulating layer and acts as a stopper in the selectively removing of the interlayer insulating layer.

12. The method for producing a semiconductor device according to claim 11, wherein the insulating layer acting as a stopper is formed in the same step as that of forming a gate oxide layer having an ONO structure.

13. The method for producing a semiconductor device according to claim 11, wherein the insulating layer acting as a stopper is formed in the same step as that of forming an anti-reflection layer.

14. The method for producing a semiconductor device according to claim 11, wherein the insulating layer acting as a stopper comprises: a silicon nitride layer formed in the same step as that of a gate oxide layer having an ONO structure gate; and a silicon nitride layer formed in the same step as that of forming an anti-reflection layer.

15. The method for producing a semiconductor device according to claim 11, comprising:
forming a plurality of solid imaging elements on a surface of a semiconductor substrate,
connecting a plurality of light-transmitting members to the surface of the semiconductor substrate in such an arrangement that each of the plurality of light-transmitting members is opposed to a light-receiving region in one of the plurality of solid imaging elements;
dicing the semiconductor substrate in such an arrangement that the wiring layer on the semiconductor substrate is partly exposed at a side surface of the semiconductor substrate;
forming a external connecting terminal to the side surface of the semiconductor substrate in correspondence to each of the plurality of solid imaging elements to provide a connected product including the plurality of solid imaging elements, each having the external connecting terminal; and
separating the connected product into each of the plurality of solid imaging elements.

16. The method for producing a semiconductor device according to claim 15, wherein the forming of the external connecting terminal comprises forming a terminal pattern in contact with a side surface of the wiring layer at the side surface of the semiconductor substrate by an ink jet method.

17. A semiconductor device comprising:
a semiconductor substrate having an element region;
an interlayer insulating layer containing an impurity;
a wiring layer for taking out a signal; and
an underlayer under the wiring layer at an edge portion of the semiconductor substrate, the underlayer having etching selectivity with respect to the interlayer insulating layer.

18. The semiconductor device according to claim 17, wherein the interlayer insulating layer is one of a BPSG layer and a PSG layer.

19. The semiconductor device according to claim 17, comprising a silicon conductive layer under the interlayer insulating layer at the edge portion of the semiconductor substrate.

20. The semiconductor device according to claim 17, wherein the underlayer is a non-doped insulating layer.

21. The semiconductor device according to claim 19, wherein the silicon conductive layer comprises polycrystalline silicon.

22. The semiconductor device according to claim 17, wherein the wiring layer is exposed at the edge portion of the semiconductor substrate and is externally connected through a wiring lead provided on a side surface of the semiconductor substrate.

23. The semiconductor device according to claim 22, comprising a protective layer above the wiring layer, wherein the wiring layer is surrounded by the underlayer and the protective layer on cross section of the edge portion of the semiconductor substrate.

24. The semiconductor device according to claim 23, which is a solid imaging element comprising: a photoelectric conversion portion that generates a charge; and a charge transferring portion comprising a charge transferring electrode that transfers the charge,
wherein the charge transferring electrode comprises: a first layer electrode of a first conductive layer; a second layer electrode of a second conductive layer; and a interelectrode insulating layer between the first and second layer electrodes,
the underlayer is one of the first and second conductive layer extending to the edge portion of the semiconductor substrate, and
the wiring layer is surrounded by the one of the first and second conductive layer and the protective layer on cross section of the edge portion of the semiconductor substrate.

25. The semiconductor device according to claim 23, which is a solid imaging element comprising: a photoelectric conversion portion that generates a charge; and a charge transferring portion comprising a charge transferring electrode that transfers the charge,
wherein the charge transferring electrode comprises: a first layer electrode of a first conductive layer; a second layer electrode of a second conductive layer; and a interelectrode insulating layer between the first and second layer electrodes,
the underlayer is a non-doped insulating layer extending to the edge portion of the semiconductor substrate, and
the wiring layer is surrounded by the interlayer insulating layer and the protective layer on cross section of the edge portion of the semiconductor substrate.

26. The semiconductor device according to claim 17, wherein the wiring layer is a metallic layer.

27. The semiconductor device according to claim 26, wherein the metallic layer comprises one of aluminum and aluminum alloy.

28. The semiconductor device according to claim 17, which is a solid imaging element of a chip size package.

29. A method for producing a semiconductor device comprising: a semiconductor substrate having an element region; an interlayer insulating layer containing an impurity; and a wiring layer for taking out a signal,
the method comprising:
forming a silicon conductive layer under the interlayer insulating layer, corresponding to a region where the wiring layer is to be formed;
selectively removing the interlayer insulating layer with a silicon conductive layer as an etching stopper; and
forming the wiring layer above the silicon conductive layer, to provide the semiconductor device in which the interlayer insulating layer is selectively removed at the edge portion of the semiconductor substrate.

30. The method for producing a semiconductor device according to 29, comprising forming the silicon conductive layer before the forming of the interlayer insulating layer, the silicon conductive layer having a different etching rate from the interlayer insulating layer.

31. The method for producing a semiconductor device according to claim 30, wherein the silicon conductive layer is a non-doped insulating layer.

32. The method for producing a semiconductor according to claim 29, comprising forming a protective layer, after the forming of the wiring layer, to cover a pattern of the wiring layer at least at the edge portion of the semiconductor substrate.

33. The method for producing a semiconductor device according to claim 30, which is a method for a producing a solid imaging device comprising: a photoelectric conversion portion that generates a charge; and a charge transferring portion comprising a charge transferring electrode that transfers the charge, the charge transferring electrode comprising: a first layer electrode of a first conductive layer; a second layer electrode of a second conductive layer; and a interelectrode insulating layer between the first and second layer electrodes,
the method comprising patterning the second layer electrode in such a manner that one of the first and second conductive layer is left on the edge portion of the semiconductor substrate as an underlayer of the interlayer insulating layer.

34. The method for producing a semiconductor device according to claim 31, which is a method for a producing a solid imaging device comprising: a photoelectric conversion portion that generates a charge; and a charge transferring portion comprising a charge transferring electrode that transfers the charge, the charge transferring electrode comprising: a first layer electrode of a first conductive layer; a second layer electrode of a second conductive layer; and a interelectrode insulating layer between the first and second layer electrodes,
the method comprising forming the non-doped insulating layer extending to the edge portion of the semiconductor substrate as an underlayer of the interlayer insulating layer.

35. The method for producing a semiconductor device according to claim 33, comprising:
forming a plurality of solid imaging elements on a surface of a semiconductor substrate,
connecting a plurality of light-transmitting members to the surface of the semiconductor substrate in such an arrangement that each of the plurality of light-transmitting members is opposed to a light-receiving region in one of the plurality of solid imaging elements;
dicing the semiconductor substrate in such an arrangement that the wiring layer on the semiconductor substrate is partly exposed at a side surface of the semiconductor substrate;
forming a external connecting terminal to the side surface of the semiconductor substrate in correspondence to each of the plurality of solid imaging elements to provide a connected product including the plurality of solid imaging elements, each having the external connecting terminal; and
separating the connected product into each of the plurality of solid imaging elements.

36. The method for producing a semiconductor device according to claim 35, wherein the forming of the external connecting terminal comprises forming a terminal pattern in contact with a side surface of the wiring layer at the side surface of the semiconductor substrate by an ink jet method.

37. The method for producing a semiconductor device according to claim 34, comprising:
forming a plurality of solid imaging elements on a surface of a semiconductor substrate,
connecting a plurality of light-transmitting members to the surface of the semiconductor substrate in such an arrangement that each of the plurality of light-transmitting members is opposed to a light-receiving region in one of the plurality of solid imaging elements;
dicing the semiconductor substrate in such an arrangement that the wiring layer on the semiconductor substrate is partly exposed at a side surface of the semiconductor substrate;
forming a external connecting terminal to the side surface of the semiconductor substrate in correspondence to each of the plurality of solid imaging elements to provide a connected product including the plurality of solid imaging elements, each having the external connecting terminal; and
separating the connected product into each of the plurality of solid imaging elements.

38. The method for producing a semiconductor device according to claim 37, wherein the forming of the external connecting terminal comprises forming a terminal pattern in contact with a side surface of the wiring layer at the side surface of the semiconductor substrate by an ink jet method.
